(19) United States
(12) Patent Application Publication
(10) Pub. No.: US 2016/0173027 A1
(43) Pub. Date: Jun. 16, 2016

(54) PHOTOVOLTAIC CELL FOR SOLAR POWER GENERATOR

(71) Applicant: Jeffrey A. Davoren, Loma Mar, CA (US)

(72) Inventor: Jeffrey A. Davoren, Loma Mar, CA (US)

(21) Appl. No.: 14/964,403

(22) Filed: Dec. 9, 2015

Related U.S. Application Data
(63) Continuation-in-part of application No. 13/969,430, filed on Aug. 16, 2013.

(51) Int. Cl. H02S 40/34; H02S 40/38; H01L 31/0216; H02S 10/40; H02S 20/30

(52) U.S. Cl. CPC H02S 40/34; H02S 10/40; H02S 20/30; H01L 31/02162; H02S 40/38

(57) ABSTRACT

A photovoltaic power generator system and method for capturing and transmitting electromagnetic radiation utilizing an infrared filter in optical communication with a photovoltaic cell.

### RELATED APPLICATIONS

This Application is a Continuation-In-Part Patent Application of co-pending U.S. patent application Ser. No. 13/969,430 filed Aug. 16, 2013 entitled “CONCENTRATOR-DRIVEN, PHOTOVOLTAIC POWER GENERATOR”, Attorney Docket No. JAD-101, which is incorporated herein by reference in its entirety, and claims any and all benefits to which it is entitled therefrom.

### FIELD OF THE INVENTION

The present invention relates to a novel and useful solar energy collector system, more particularly a photovoltaic cell for conversion of solar electromagnetic energy to electrical energy.

### BACKGROUND OF THE INVENTION

Solar energy has served as a means for generating electricity and heat at an accelerated pace. Although solar energy comprises a very abundant source, conversion to useable forms of energy is expensive. Solar energy emitted from the Earh's sun comprises many types of radiation, including but not limited to ultraviotet, visible and infrared.

A typical photovoltaic cell consists of a layer of N-type material, i.e., material in which there exists valence excess number of electrons, in intimate contact with a layer of P-type materials, i.e., materials in which there exist a deficiency in the number of valence electrons. A metallic or other conductive material is used as a backing to the layered pair of materials. Thus, as excitation photons impinge upon the N-type layer of material having an excess of electrons, an electrical potential is created between the metallic backing and the top surface of the layer of N-type material

In the past, many systems have been devised to capture solar radiation. For example, solar panels have been employed in fixed arrays to directly convert solar radiation to electricity. In addition, circulation membranes have been employed to heat water for use within buildings and for use in swimming pools and spas. Other systems employ concave reflectors that concentrate solar radiation substantially at a point, where it is then employed to heat materials or is transferred as light to secondary conversion apparatuses.

For example, U.S. Pat. Nos. 4,841,946 and 5,540,216 show concave solar power collectors which track movement of the sun and convert the solar radiation into heat.

U.S. Pat. No. 5,877,874 shows a holographic planar concentrator which collects optical radiation from the sun for conversion through photovoltaic cells into electrical energy. Also, fiber optic light guides transfer collected light to an interior of a building for illumination or for the purpose of producing hot water.

U.S. Pat. No. 5,581,447 shows a solar skylight apparatus in which light is collected from the sun and transmitted to the inside of a building through a fiber optic cable. The light is then dispersed within a room to provide illumination.

U.S. Pat. Nos. 4,943,125 and 5,575,860 show solar collectors that employ fiber optic fibers for use as energy sources.

A solar collection device which is efficient, powerful, and simple in construction would be a notable advance in the field of solar energy production.

U.S. Pat. Nos. 6,831,221 and 7,718,887 are both directed to conversion of heat energy to electrical energy, however the present invention is directed to conversion of solar radiation, from which infrared components have been removed, to electrical energy.

Likewise, U.S. Pat. No. 7,973,236 teaches a combination of ultra-violet/infrared filter in conjunction with an electro-optic shutter, but not a photovoltaic cell.

### SUMMARY OF INVENTION

The present invention is a novel and useful collection device for capturing and transmitting electromagnetic radiation received from the sun. The present invention incorporates an infrared (IR) filter and photovoltaic cell. A beam of incoming solar radiation passes through an infrared filter, which screens out the infrared portion of the solar spectrum, thus preventing heat damage and resulting loss of efficiency of the photovoltaic cell. The photon rich visible light portion of the spectrum then strikes and activates the photovoltaic cell, thus generating a flow of electrical energy.

The device of the present invention can optionally be mounted on an existing-type tracking system which is also known in the art; or a novel, custom tracking system, to keep the photovoltaic cell in direct alignment with the sun from dawn to dusk, as the sun moves across the sky, thereby maximizing power output.

In order to eliminate heat from infrared radiation, an infrared (IR) filter is placed adjacent the photovoltaic cell. Infrared (IR) energy is invisible radiant energy, i.e., electromagnetic radiation with longer wavelengths than those of visible light. IR extends from the nominal red edge of the visible spectrum at 700 nanometers to the far IR at about 1 mm.

It is therefore an object of the present invention to provide a photovoltaic power generator system and method for capturing and transmitting electromagnetic radiation utilizing an infrared filter in optical communication with a photovoltaic cell.

It is a further object of the present invention to provide a collection device for capturing and converting visible-wavelength, electromagnetic radiation radiating from the sun into electrical energy that is simple to manufacture and to operate.

Another object of the present invention is to provide a device for capturing and converting electromagnetic radiation from the sun into electrical energy in an efficient manner.

A further object of the present invention is to provide a collection device for capturing and converting electromagnetic radiation that is suitable for congested or urban areas.

A further object of the present invention is to avoid overheating or otherwise damaging the photovoltaic cell during transmission of focused electromagnetic radiation into electrical energy by using an infrared (IR) filter.

The invention possesses other objects and advantages especially as concerns particular characteristics and features thereof which will become apparent as the specification continues.

### BRIEF DESCRIPTION OF THE DRAWINGS

FIG. 1 is a representative top view of an infrared filter 102 of the present invention adjacent a photovoltaic cell 104 of the present invention.

FIG. 2 is a representative section view of a power generating unit 200 of the present invention.

FIG. 3 is a schematic view representing transduction of solar energy into electricity.

FIG. 4 is a representative top view of an array 400 of power generating units 200 of the present invention.

FIG. 5 is a representative isometric view of an automated solar tracking device 500 for an array 400 of power generating units 200 of the present invention.

For a better understanding of the invention reference is made to the following detailed description of the preferred embodiments thereof which should be taken in conjunction with the prior described drawings.

### DETAILED DESCRIPTION OF THE PREFERRED EMBODIMENT

The description that follows is presented to enable one skilled in the art to make and use the present invention, and is provided in the context of a particular application and its requirements. Various modifications to the disclosed embodiments will be apparent to those skilled in the art, and the general principals discussed below may be applied to other embodiments and applications without departing from the scope and spirit of the invention. Therefore, the invention is not intended to be limited to the embodiments disclosed, but the invention is to be given the largest possible scope which is consistent with the principals and features described herein.

Various aspects of the present invention will evolve from the following detailed description of the preferred embodiments thereof which should be taken in conjunction with the hereinabove delineated drawings.

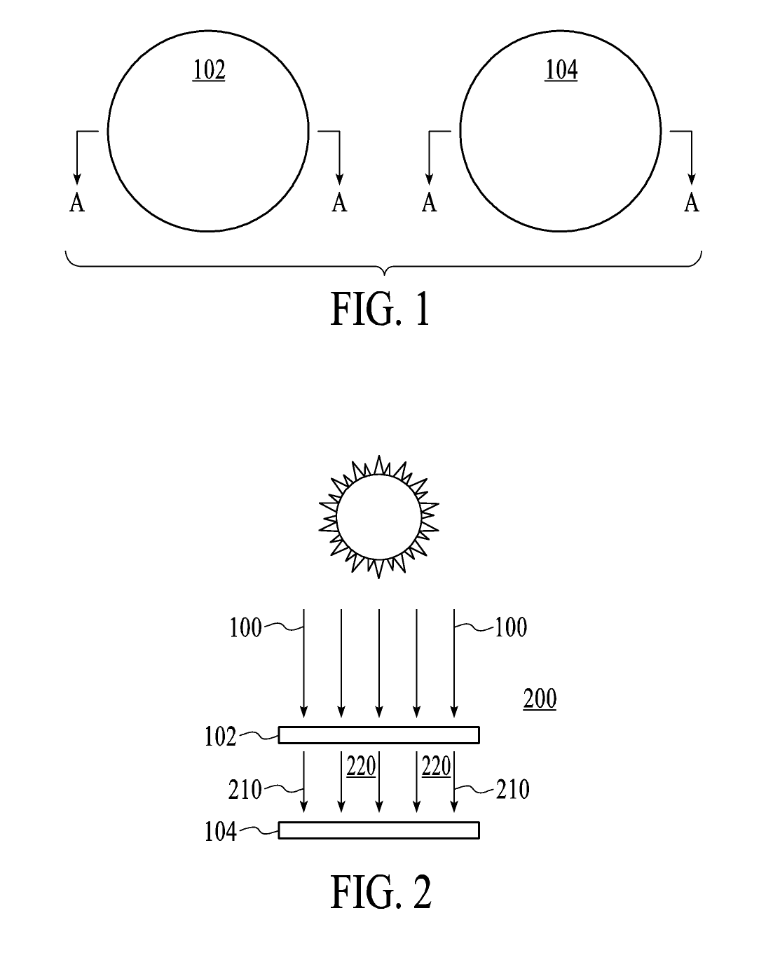

FIG. 1 is a representative top view of an infrared filter 102 of the present invention adjacent a photovoltaic cell 104 of the present invention. As shown, the infrared filter 102 and photovoltaic cell 104 are both roughly the same size and shape. It will be understood that various sizes and shapes of infrared filter 102 and photovoltaic cell 104 are available commercially as well as in custom built devices. In addition, selection of infrared filter 102 and photovoltaic cell 104 can be based on power output, conversion efficiency, durability and estimated lifespan, and other operating parameters including cut-off ranges, such that sustainable, optimum power generation is achieved.

FIG. 2 is a representative section view of a power generating unit 200 of the present invention. Since it is possible that a portion of the flow of solar energy 100 will contain energy in the infrared wavelength-range, the photovoltaic cell 104 could develop overheating problems. Thus, direct, and unfiltered solar energy 100 enters infrared filter device 102.

Infrared filter device 102 is an infrared cut-off filter, sometimes called an IR filter or heat-absorbing filter. In one embodiment, infrared filter device 102 is movably positioned. The purpose of infrared filter device 102 is to block infrared wavelength-radiation in the flow of solar energy 100 while passing a flow of filtered solar energy 210 to prevent overheating when it enters photovoltaic cell 104. In alternative embodiments, other types of filters such as UV filter or other wavelength-specific filters can be added or replaced as needed.

Filtered solar energy 210 leaves infrared filter device 102 and enters photovoltaic cell 104. Photovoltaic cell 104 is a device that converts the photonic energy of incoming filtered visible wavelength, solar energy 210 directly into electricity by the photovoltaic effect. In one embodiment, photovoltaic cell 104 has various electrical characteristics e.g. current, voltage, or resistance to suit specific needs of the present invention. Generally, when photovoltaic cell 104 is exposed to filtered solar energy 210, the photovoltaic cell 104 generates an electric current without the need for any external power source.

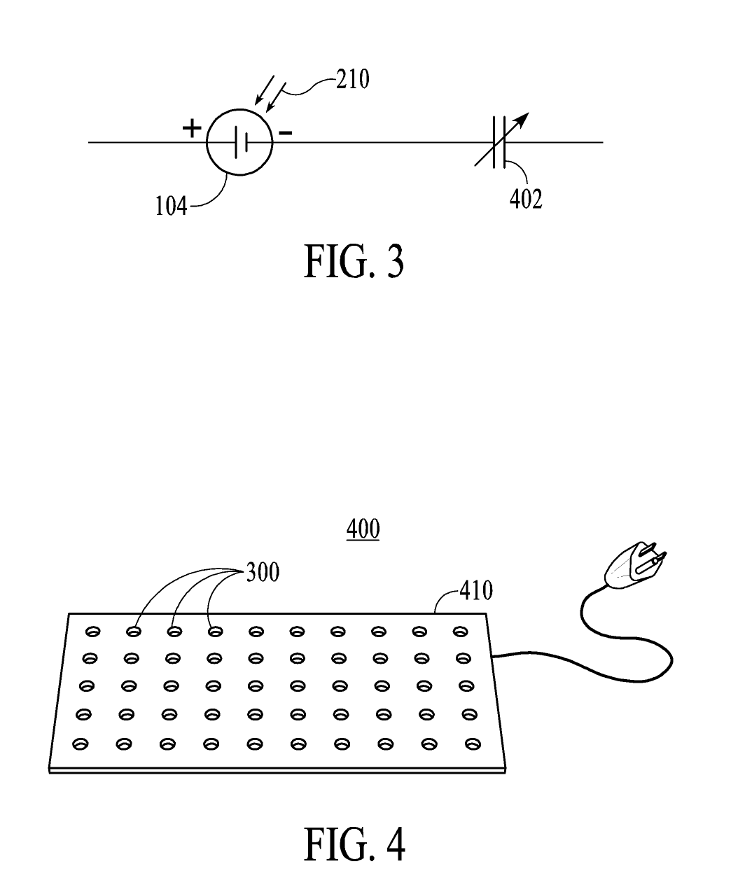

FIG. 3 is a schematic view representing transduction of solar energy into electricity. Photovoltaic cell 104 converts energy from filtered solar energy 210 into electrical energy denoted by electrical potential 402. Electrical potential 402 can be coupled to a capacitor or used to recharge batteries for storage of the electrical energy generated, as desired. Alternatively, the energy potential 402 can be used to power electrical devices directly. Users can also connect energy potential 402 to a more elaborate electrical circuit with other electrical components such as transducers, transformers, etc. for other purposes, or provide electrical power to the grid, i.e., puts power back into a private or general municipal electrical power system.

FIG. 4 is a representative view of an array 400 of power generating units 200 of the present invention. As shown, dozens of individual power generating units 200, each containing a photovoltaic cell 104, can be placed into a suitable armature or framework 410. An electrical connection network interconnects each of the power generating units with a wiring harness or coupling 420 for utilization of the electrical energy 402 generated by the power generating units 200 of the present invention.

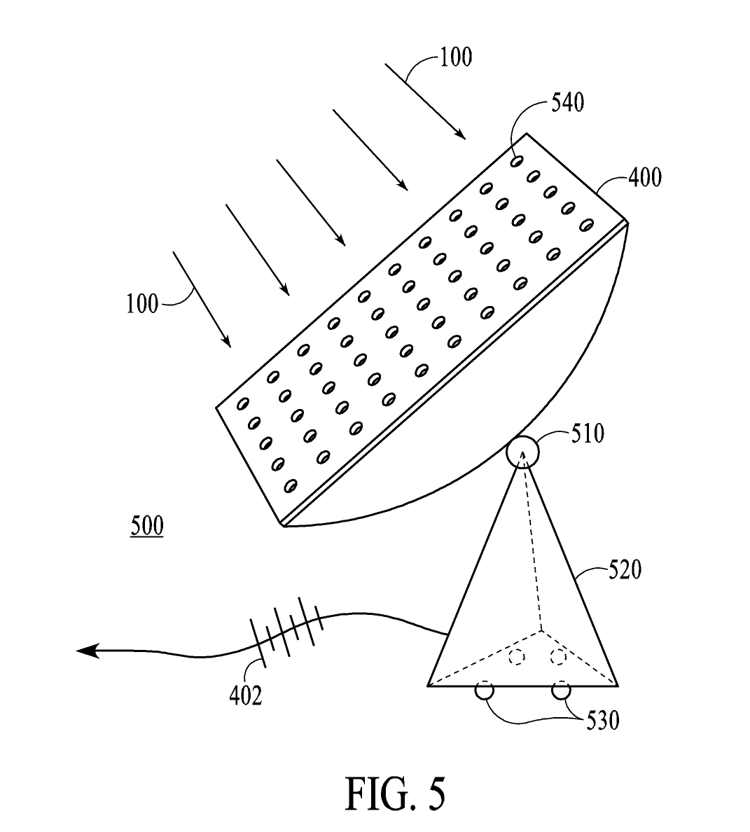

FIG. 5 is a representative isometric view of an automated solar tracking device 500 for an array 400 of power generating units 200 of the present invention. As shown in FIG. 5, array 400 is supported and elevated by mobile tracking device 500. In one embodiment, mobile tracking device 500 may be of a conventional configuration to provide a sturdy and stable base for array 400 in an outdoor environment. Array 400 is anchored, fixed, and pivots mechanically, flexibly and adjustably on mobile tracking device 500. Mechanical coupling 510 such as a hinge, ball-and-socket joint, universal joint, etc., permits array 400 to rotate and move to whatever orientation is most advantageous for solar collection, i.e., perpendicular to the rays of the sun. This allows a controllable range of two-dimensional motion such that the array 400 is capable of tracking the sun as it travels across the sky on a daily orbital basis.

Tracking device 500 can be manually operated or controlled with an electrical/electronic motor. Support stand 520 can be mobile with wheels or other means such as wheels-and-track system 530 so the entire power generator 500 can be moved or relocated to locations that are most receptive to strong sun exposure. Since such two-axis tracking system supports are known in the art, mobile stand 520 is only partially shown in the drawings. In one embodiment, physical locations of the present invention 500 in the wheels-and-track system 530 and tilting angles of array 400 can be pre-programmed according to locations of the sun during the day/year utilizing a solar sensor 540 and associated electronics for controlling the mechanical coupling 510.

In one embodiment, photovoltaic cell 104 is movable and can be fixed relative the filter 102. Photovoltaic cell 104 is also connected to an electric circuit so the electrical energy generated by the photovoltaic cell 104 can be transmitted to remote locations. In one embodiment, the electric circuit can be installed in the structural frame of the array 400 or in the support base 520 of the mechanical tracking device 500 or other configuration.

While in the foregoing, embodiments of the present invention have been set forth in considerable detail for the purposes of making a complete disclosure of the invention, it may be apparent to those of skill in the art that numerous changes may be made in such detail without departing from the spirit and principles of the invention.

Although the invention herein is to be understood as described, these descriptions are merely illustrative of the principles and applications of the present invention. Therefore, it is understood that numerous modifications may be made to the illustrative embodiments and that other modifications maybe devised without departing from the scope and functions of the inventions as defined by the claims to be followed.

Unless defined otherwise, all technical and scientific terms used herein have the same meaning as commonly understood by one of ordinary skill in the art to which the present invention belongs. Although any methods and materials similar or equivalent to those described can be used in the practice or testing of the present invention, the preferred methods and materials are now described. All publications and patent documents referenced in the present invention are incorporated herein by reference.

While the principles of the invention have been made clear in illustrative embodiments, there will be immediately obvious to those skilled in the art many modifications of structure, arrangement, proportions, the elements, materials, and components used in the practice of the invention, and otherwise, which are particularly adapted to specific environments and operative requirements without departing from those principles. The appended claims are intended to cover and embrace any and all such modifications, with the limits only of the true purview, spirit and scope of the invention.

I claim:

1. A photovoltaic power generator for capturing electromagnetic radiation and converting it to electrical energy, the photovoltaic power generator comprising:
one or more power generating units, each power generating unit having:
an infrared filter having a first side, a second side and an outer rim, the first side receiving electromagnetic radiation from a solar source, the infrared filter transmitting the electromagnetic radiation having wavelengths outside of the infrared range while filtering out the electromagnetic radiation having wavelengths within the infrared range;
a photovoltaic cell in osptical communication with the infrared filter, the photovoltaic cell having at least an upper layer of material and a lower backing, the photovoltaic cell positioned such that filtered electromagnetic radiation emanating from the second side of the infrared filter enters the photovoltaic cell through the upper layer of material such that the filtered beam of electromagnetic radiation is converted into electrical energy by the photovoltaic cell; and
an electrical output in electrical communication with the photovoltaic cell, wherein the electrical energy created by the photovoltaic cell of the one or more power generating units can be used or stored as desired.

2. The photovoltaic power generator of claim 1 in which the one or more power generating units comprises an array of power generating units.

3. The array of power generating units of claim 1 in which the electrical outputs of each of the one or more power generating units are electrically connected.

4. The photovoltaic power generator of claim 1 in which the second side of the infrared filter is in direct contact with the upper layer of the photovoltaic cell.

5. The photovoltaic power generator of claim 1 in which there is a gap between the second side of the infrared filter and the upper layer of the photovoltaic cell.

6. The photovoltaic power generator of claim 1 in which the gap between the second side of the infrared filter and the upper layer of the photovoltaic cell is sealed to the atmosphere.

7. The photovoltaic power generator of claim 1 in which the gap between the second side of the infrared filter and the upper layer of the photovoltaic cell is at a pressure greater than atmospheric.

8. The photovoltaic power generator of claim 1 in which the gap between the second side of the infrared filter and the upper layer of the photovoltaic cell is at a pressure less than atmospheric.

9. The photovoltaic power generator of claim 1 further comprising a support stand having a base and a top, said top further including coupling mechanism to provide support and permit rotation and other movement simultaneously of the one or more power generating units.

10. The photovoltaic power generator of claim 9 in which said coupling mechanism comprises a ball-and-socket joint.

11. The photovoltaic power generator of claim 9 in which said coupling mechanism comprises a hinge joint.

12. The photovoltaic power generator of claim 9 in which the support stand is made mobile by a traveling system.

13. The photovoltaic power generator of claim 12 in which the traveling system is a plurality of wheels.

14. The photovoltaic power generator of claim 9 in which the coupling mechanism and the traveling system are pre-programmed by a computer system, allowing the power generator to attain the best position and the reflector to attain the best tilting angle for maximum exposure to the electromagnetic radiation from the source.

15. The photovoltaic power generator of claim 1 further comprising an electrical circuit, the electrical circuit connected to the electrical output of the one or more power generating units, the electrical circuit adapted to receive, transmit, store and discharge electrical energy generated.

16. The photovoltaic power generator of claim 15 in which the electrical circuit further comprises a plurality of capacitors, the capacitors adapted to store the generated electrical energy electrostatically in an electric field.

17. The photovoltaic power generator of claim 15 in which the electrical circuit further comprises a plurality of batteries, the batteries adapted to store the generated electrical energy chemically.
